(19) United States
(12) Patent Application Publication
(10) Pub. No.: US 2011/0049532 A1
(43) Pub. Date: Mar. 3, 2011

(54) SILICON CARBIDE DUAL-MESA STATIC INDUCTION TRANSISTOR

(75) Inventors: Bruce Odekirk, Bend, OR (US); Francis K. Chai, Bend, OR (US); Edward W. Maxwell, Bend, OR (US)

(73) Assignee: MICROSEMI CORPORATION, Bend, OR (US)

(21) Appl. No.: 12/870,699

(22) Filed: Aug. 27, 2010

Related U.S. Application Data
(60) Provisional application No. 61/237,941, filed on Aug. 28, 2009.

(51) Int. Cl. H01L 29/24; H01L 21/336

(52) U.S. Cl. 257/77; 438/285; 257/E29.104; 257/E21.409

(57) ABSTRACT

A dual-mesa static induction transistor (SIT) structure includes a silicon carbide substrate having a layer arrangement formed thereon. Laterally spaced ion implanted gate regions are defined in the layer arrangement. Source regions are defined in the layer arrangement. Each of the source regions can include a channel mesa having a source mesa disposed thereon. The source mesa includes sidewalls relative to a principal plane of the substrate defining a horizontal dimension thereof. The channel mesa includes slanted sidewalls relative to the source mesa and the principal plane of the substrate. Also disclosed is a method of fabricating a dual-mesa SiC transistor device. The method includes implanting ions at a normal relative to a principal plane of the substrate to form gate junctions in upper portions of the substrate and lateral portions of the slanted channel mesas.

### CROSS REFERENCE TO RELATED APPLICATION

This application claims the benefit of U.S. provisional application Ser. No. 61/237,941, filed Aug. 28, 2009, herein incorporated by reference.

### BACKGROUND

1. Technical Field

The present invention relates to the fabrication of semiconductor devices in high band gap materials such as silicon carbide, and more particularly to the fabrication of dual-mesa static induction transistors.

2. Discussion of Related Art

Silicon carbide (SiC) Static Induction Transistors (SITs) have been developed for high power radio frequency (RF) applications such as Radar, Avionics and TV Transmission. Such devices are described in U.S. Pat. Nos. 5,705,830 and 5,903,020. The conventional devices have been limited in frequency range thus far to high frequency (HF) in the range of 100-200 MHz and ultrahigh frequency (UHF) in the range of 400-500 MHz for the various applications due to excessive power gain roll-off at frequencies above 500 MHz.

There are many important applications for Radar and Avionics RF power transistors in L-Band (1.0-1.5 GHz) for which the conventional devices can not address. Consequently, high power L-Band Radar/Avionics systems are forced to use existing silicon bipolar devices that have much lower power densities, require lower operating voltages, and have significant temperature limitations.

It would therefore be desirable to use SiC SIT devices that operate at significantly higher voltages, power densities, and junction temperatures than existing silicon devices in L-Band systems. Performance advantages of SiC devices over silicon devices are made possible by the fundamental material properties of SiC. For instance, higher voltage operation with lower on-resistance arises from the 10× higher breakdown field strength of SiC compared to silicon. Higher junction temperature operation arises from the much larger bandgap (3.26 eV for 4H-SiC, compared to 1.1 eV for silicon). Nevertheless, conventional SiC devices suffer from various inefficiencies.

U.S. Pat. No. 5,705,830 describes a conventional SiC SIT having a vertical conducting channel that uses Schottky barrier gate control. The source contact is on a narrow top mesa, the drain contact is on the back of the die, and the Schottky gate contact is formed on the sidewalls of a channel mesa. The requirement of making Schottky contact to the channel mesa vertical sidewalls imposes severe manufacturing difficulties, which are overcome only by use of several layers of e-beam lithography and precise angled metal evaporation and lift-off. Consequently the manufacture of such devices requires very expensive equipment and considerable engineering supervision. In addition, the Schottky gate has poor breakdown and reverse leakage characteristics resulting in reliability problems that are difficult to overcome.

An improvement over the Schottky gated SIT is described in U.S. Pat. No. 5,903,020. In the '020 patent, a single-mesa is used and the Schottky barrier gate is replaced by a junction gate. The junction gate is formed by implanting acceptor impurities, typically aluminum (Al), into the gate region using the channel mesa, with oxide sidewall spacers as the implant mask. Hence, the p-type gate is self-aligned to the n-type vertical channel. This is simpler to manufacture using conventional optical stepper lithography, and no metal contacts need to be made to the sidewall of the channel mesa.

In addition, the junction gate of the '020 patent has a larger barrier height (˜3.0 eV compared to ˜1.4 eV for the Schottky gate), which enables wider channel mesas to be formed for the same channel pinch-off voltage, V_{P}. Because of the larger barrier height, the junction gate has a higher gate turn-on voltage (˜2.5 V) than the Schottky gate (˜1.0 V), which provides substantially higher maximum channel current (and hence, power) capability. Moreover, the junction gate has higher breakdown voltage and lower reverse bias gate leakage, making a more robust and reliable device.

As a result, the single-mesa implanted junction-gated SIT provides a robust RF power transistor for applications through UHF band. Indeed, these devices have produced the highest power UHF transistors available to date.

FIG. 1 shows an SEM image of a cross section of the conventional single-mesa implanted SiC SIT for UHF power transistors. The p-type (implanted) regions 101 show up as lighter regions in these SEM images. The source contacts are on top of the single-mesa as indicated by 107 in FIG. 1, and the drain contact is on the back of the chip (not shown). Hence, the single-mesa structure forms both the source contact and the vertical transistor channel, and current flow is modulated by voltage applied to the gate and drain contacts.

Several frequency-limiting factors are inherent to the conventional single-mesa topology. The gate junction is formed by implantation directed normally to the wafer surface at high energy. Consequently, and as shown in FIG. 1, the gate perimeter is defined by the lateral and side straggle of the highest energy implant and the resulting channel has a trapezoidal shape, as shown in Region A. An ideal channel would be of constant width throughout the length of the channel. The channel widening from the source to drain end shown in FIG. 1 reduces the gate control of channel current, which is particularly detrimental to high frequency performance. In addition, the extended perimeter of the gate junction in Region B of FIG. 1 contributes excess parasitic gate capacitance (C_{gg}) that further reduces the high frequency capability.

### SUMMARY OF EMBODIMENTS OF THE INVENTION

In an example embodiment of the invention, a dual-mesa static induction transistor (SIT) structure is provided. The dual-mesa SIT can include, for example, a silicon carbide substrate having a layer arrangement formed thereon. Laterally spaced ion implanted gate regions are defined in the layer arrangement. In addition, source regions are defined in the layer arrangement. Each of the source regions can be positioned adjacent to respective ones of the gate regions. Moreover, each of the source regions can include a channel mesa having a source mesa disposed thereon.

The source mesa includes sidewalls upright relative to a principal plane of the substrate, the principal plane of the substrate defining a horizontal dimension thereof. The channel mesa includes slanted sidewalls relative to the source mesa sidewalls and the principal plane of the substrate. Sidewalls of the source mesa are recessed laterally relative to sidewalls of the channel mesa. The channel mesa can have at least one slanted sidewall angled at between 2 and 15 degrees from a vertical reference line perpendicular relative to the principal plane or horizontal plane of the substrate. The vertical reference line intersects a vertex located at an upper corner of the channel mesa. The source regions include a channel having a substantially constant width along the length of the channel. The source mesa for each source region is coupled to an ohmic source contact. Each of the source regions is coupled to a source bus through each source mesa.

In another example embodiment of the present invention, a method of fabricating a static induction transistor device on a silicon carbide substrate is provided. The method can include the steps of, for example, forming a silicon carbide contact layer having a first dopant type on the substrate, forming a first implant mask layer on the silicon carbide contact layer, forming source mesas in the silicon carbide contact layer using the first implant mask layer, forming a second implant mask layer on the source mesas and the substrate, forming channel mesas positioned below the source mesas. The channel mesas are formed with sidewalls slanted at an angle of between 2 and 15 degrees relative to a normal of a principal plane of the substrate.

The method can further include, for example, implanting ions at a normal relative to the principal plane of the substrate to form gate junctions having a dopant type opposite the first dopant type in upper portions of the substrate and lateral portions of the slanted channel mesas. Thus, a channel can be formed having a substantially constant width.

In some embodiments, the method includes forming a source ohmic contact on the source mesa, forming a gate ohmic contact on each gate junction, forming a gate overlay metal on each of the gate ohmic contacts, and forming an interlayer dielectric film on the ohmic contacts and the gate overlay metal.

In some embodiments, the method includes forming source and gate contact openings in the interlayer dielectric film, forming a metal source bus in the source contact openings, and forming a metal gate bus in the gate contact openings.

In some embodiments, the method includes forming a source bond pad on the source bus, and forming a gate bond bad on the gate bus.

In some embodiments, the method includes forming a passivation layer on the source bond pad and the gate bond pad, and forming one or more bond pad openings in the passivation layer.

The foregoing and other features and advantages of the invention will become more readily apparent from the following detailed description of a preferred embodiment of the invention that proceeds with reference to the accompanying drawings.

### BRIEF DESCRIPTION OF THE DRAWINGS

FIG. 1 is a cross-sectional view showing a conventional single-mesa implanted SIT for UHF power transistors.

FIGS. 2 through 7 show cross-sections of a dual-mesa silicon carbide static induction transistor (dual-mesa SiC SIT) through various stages of fabrication, according to embodiments of the present invention.

FIG. 8 shows the completed dual-mesa SiC SIT according to embodiments of the present invention.

FIG. 9 is a graph comparing the blocking voltage gain performance of the embodiments of the present invention to the prior art.

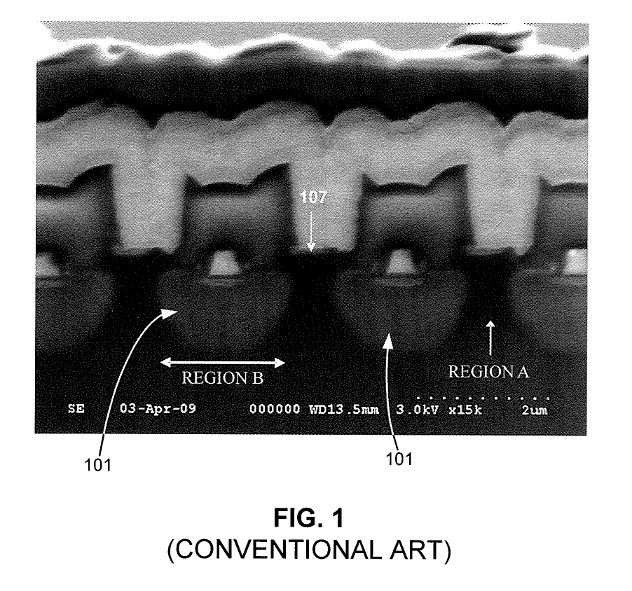

### DETAILED DESCRIPTION

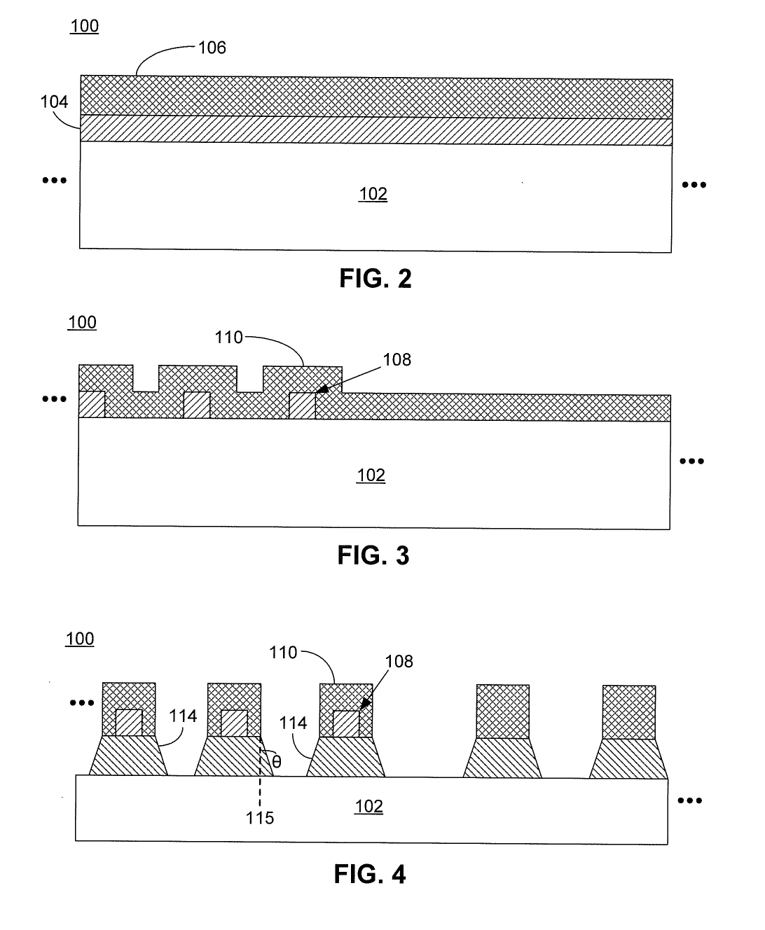

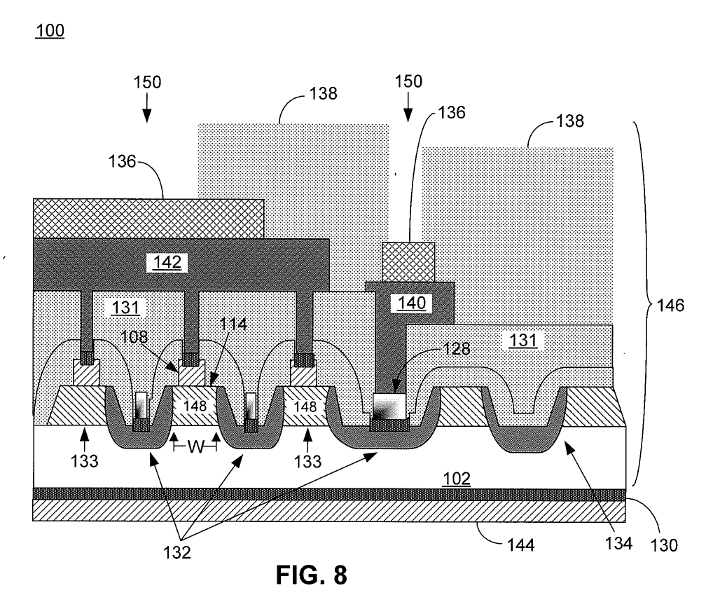

FIGS. 2 through 7 are cross-sectional views of a dual-mesa silicon carbide (SiC) Static Induction Transistor (SIT) at various steps in the manufacturing process. FIG. 8 shows the completed dual-mesa SiC SIT according to embodiments of the present invention. Regions and elements are referenced using consistent numerals throughout. The drawings included herein are not necessarily to scale.

The preferred first embodiment of the present invention includes a method of fabricating the SiC SIT as described with reference to FIGS. 2 through 7. A dual-mesa SIT is described in which a channel mesa is formed with slanted sidewalls. A source mesa is disposed on the channel mesa. The source mesa sidewalls are recessed laterally relative to the sidewalls of the channel mesa. It should be understood that the inventive principles disclosed herein are not limited to the methods for manufacturing the improved SiC SIT illustrated and described, except as specifically limited in the claims. Rather, the inventive principles disclosed herein may be extended to other embodiments, such as equivalent methods for achieving the same or similar structures.

Although various parameters are described herein associated with the various described fabrication steps (i.e., parameters such as lengths of time, temperatures, implant doses and energies, the thickness or depth of various portions of the semiconductor devices, and ranges of chemical compositions in compounds), it will be understood that the parameters described herein are associated merely with particular embodiments of the present invention, and therefore not limiting of the invention except where expressly claimed.

FIG. 2 shows the fabrication of this structure in the initial stages. A SiC substrate 102, with epitaxial layers disposed thereon to define the drift region and the channel region, comprises layer 102, capped with a highly doped source contact layer 104. The SiC substrate is typically 4H polytype, but may also be 6H, 3C, or any other suitable polytype of SiC. The substrate layer 102 is preferably n-type with a resistivity less than 0.10 ohm-cm.

A buffer layer may be grown on the substrate wafer prior to drift layer growth. This buffer layer is n-type with a typical donor concentration of 5×10¹⁷ to 1×10¹⁹ cm⁻³, and a thickness of between 0.25 and 1.0 μm. A lower doped n-type drift layer is then grown on the buffer layer to provide the desired transistor blocking voltage level. Donor concentrations for the drift layer are preferably 1×10¹⁵ to 1×10¹⁷ cm³. Drift layer thickness may be in the range 1 to 15 μm. After the drift layer is grown, an optional n-type channel layer can be grown thereon to provide efficient channel conduction characteristics. The channel layer doping is typically in the range 1×10¹⁶ to 5×10¹⁷ cm³, with a thickness in the range of 0.5 to 5 μm. These layers together, i.e., the SiC substrate, the buffer epi layer, the drift epi layer, and the channel epi layer, correspond to substrate layer 102.

On top of layer 102 is formed a highly doped n-type layer 104 to facilitate formation of source ohmic contacts. This layer can be epitaxially grown or formed by ion implantation of suitable donor species (e.g., such as nitrogen or phosphorous). The donor concentration in this layer can be in the range of 1×10¹⁸ to 2×10¹⁹ cm⁻³, with a thickness in the range of 0.1 to 0.5 μm. Layer 106 is a deposited dielectric film suitable for use as an ion implantation mask for implanting at wafer temperatures above, for example, 400° C. The film 106 can be silicon dioxide, silicon nitride, or silicon oxynitride deposited by thermal CVD or plasma enhanced CVD. In a preferred embodiment, the film 106 is silicon dioxide (SiO₂) deposited by plasma-enhanced chemical vapor deposition (PE-CVD) to a thickness in the range of 0.3-1.0 μm.

Referring to FIG. 3, a source mesa 108 is formed by conventional photoresist patterning and reactive ion etching of the SiO₂ layer 106 and the SiC source contact layer 104, resulting in source contact mesas 108 shown in FIG. 3. The reactive ion etching (RIE) in our embodiment uses sulfur hexafluoride (SF6) or nitrogen trifluoride (NF₃), but any fluorine-containing etch gas may be used to etch both layers.

Alternatively, a metal etch mask can be used to reduce any slope to the source mesa sidewalls. When the metal etch mask is used, a nickel (Ni) or aluminum (Al) film is patterned over the top of the intended source mesa region by photolithography and lift-off. The resulting source mesa 108 sidewall is upright, and can have a rectangular or trapezoidal shape. For example, the slope of the sidewalls of the source mesa 108 is shown as vertical, but can be in the range of 0 to 15 degrees. The source mesa etch is made deeper than the highly doped source contact layer 104 in order to establish adequate gate/source breakdown voltage. The source mesa 108 can be etched between 0.1 and 0.5 μm below the lower surface of layer 104 into layer 102; hence, although not shown, the source mesa 108 includes the high doped contact region overlying a portion of the medium doped channel region.

After source mesa etching is complete, a second dielectric implant mask layer 110 is deposited over the initial implant mask layer 106 in order to provide adequate implant blocking as well as to provide a sidewall spacer for the source mesa 108. Subsequent to the source mesa etching and the second implant mask deposition, photolithography and reactive ion etching (RIE) are used to pattern and etch the channel mesa 114 as shown in FIG. 4. The patterning and etching can result, for example, in stripe-shaped trenches between the channel mesas 114. Etching is again done using RIE with fluorine-containing etch gases. The photoresist profile and etch characteristics are set to provide a slope to the channel mesa sidewall, which enables single-pass vertical ion implantation of the gate junction.

The slope θ relative to the normal 115 to the wafer surface is between 2 and 15 degrees. In other words, the channel mesa 114 can have at least one slanted sidewall angled at between 2 and 15 degrees from a vertical reference line 115 relative to a principal plane of the substrate 102. The vertical reference line 115 intersects a vertex located at an upper corner of the channel mesa 114, as shown in FIG. 4.

The photoresist and etching characteristics can be established to produce these structures in several ways. For instance, high-temperature flowing of the photoresist after patterning can create an angled structure that will be replicated in the SiC during RIE by normal etch pattern transfer. Alternatively, the etch gas chemistry can be modified (e.g., by addition of oxygen and/or carbon constituents to the gas) to allow a fixed lateral erosion rate of the photoresist. The lateral erosion of the photoresist during the etch results in a sloped mesa sidewall. In other words, a trench is formed between adjacent mesas with inwardly sloping sidewalls. Each mesa between two trenches thus has a trapezoidal shape.

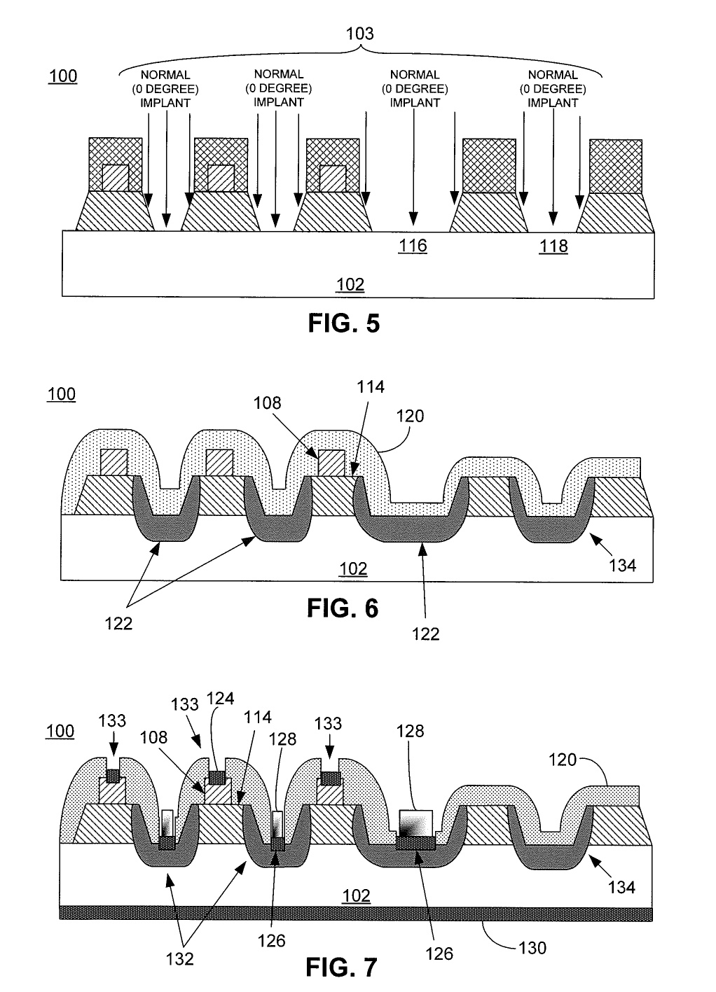

FIG. 5 depicts the acceptor ion implant step 103 used to form the gate junction. FIG. 6 shows the formed gate junction. The following description proceeds with reference to FIGS. 5 and 6. The sloped channel mesa sidewalls 114 allow both sides of each mesa 114 to be implanted simultaneously with a single normal implant 103. In some embodiments of the present invention, ions are implanted in the channel mesa 114 at an acute angle relative to the sidewalls of the channel mesa 114.

It is well-known that ion implantation damage in SiC is very difficult to eliminate unless the implantation is done at an elevated wafer temperature. In our preferred embodiment, ion implantation is done at 600° C., but it can be done at any temperature in the range 400-1000° C. Acceptor ion species can be aluminum (Al) or boron (B). In our preferred embodiment, Al ions are implanted in the energy range 20-120 keV and with a dose in the range 10¹⁴ to 10¹⁶ cm².

In addition to forming the gate junction 122 in region 116, the acceptor implants also form junction extension 122, and guard rings 134 in region 118 to enable high blocking voltages. If deeper junction regions are desired in structures 116 and 118, these can be patterned and implanted separately. Subsequently, the implant mask films are removed from the wafer by wet etching and the wafer is annealed in argon (Ar) at 1675° C. The implant anneal can be performed at any temperature in the range 1500-1800° C.

Referencing FIG. 6, after implant anneal, a surface passivation film 120 is formed on the wafer, that is, on the source mesas 108, channel mesas 114, gate junctions 122 and one or more P⁺ guard ring structures 134. In the preferred embodiment depicted in FIG. 6, the film 120 consists of or includes plasma-enhanced chemical vapor deposition borophosphosilicate glass (PE-CVD BPSG), which is flowed to provide good step overage over the dual-mesa stack 108/114. Any conventional dielectric film such as silicon dioxide, silicon oxynitride or silicon nitride can also be used as the surface passivation layer.

The implanted p-type gate junctions 122 formed by the implant and anneal steps then define the transistor channel length (i.e., in the vertical direction from channel mesa top to the bottom of the implant junction) and the channel width (i.e., the horizontal distance between p-type regions 122 at the bottom of the channel mesa). The channel length so defined determines the transconductance (gₘ) of the transistor, and the channel length and channel width together determine the V_{P} of the transistor. The total gate capacitance (C_{gg}) is determined by the perimeter length of the p-type gate region, and includes intrinsic gate capacitance in the vertical direction of the channel mesa and extrinsic ‘parasitic’ gate capacitance in the horizontal direction between channel mesas. The transistor cutoff frequency, fₜ, depends on the ratio: gₘ/C_{gg}. Therefore, it is beneficial to minimize C_{gg} and maximize gₙ, to achieve desired high-frequency power amplification.

In some embodiments of the present invention, the channel length is determined by channel mesa etch depth and implant energy. Both of these are easily controlled in a production environment. The manufacturability enhancements associated with embodiments of this invention make possible repeatable fabrication of such devices. The use of lower energy implants for this dual-mesa SIT (e.g., ˜30-50 keV in the preferred embodiment) compared to the typical 175 keV used in the single-mesa SIT significantly reduces the extension of the gate junction in the parasitic region, which in turn reduces the parasitic gate capacitance.

Referencing FIG. 7, ohmic contacts 130 are applied to the back of the wafer to form the drain contact 130. Photolithography and RIE are used to form openings for the source ohmic contacts 124 associated with the source regions 133, and the gate ohmic contacts 126 associated with the gate regions 132. Each of the source ohmic contacts 124 is coupled to a corresponding one of the source mesas 108. Similarly, each of the gate ohmic contacts 126 is coupled to a corresponding one of the gate junctions 122.

The ohmic contacts can be formed by alloying a thin Ni film having, for example, a thickness of 500-1000 angstroms, with the SiC to form Ni₂Si. The Ni film is most typically patterned in the contact openings by lift-off. The anneal process used to form the Ni₂Si ohmic contact can include any number of steps, and generally includes a final anneal at 850-1000° C. All of the ohmic contact regions can be formed together.

After the ohmic contacts are formed, gate overlay metal 128, which can consist of or include titanium (Ti), platinum (Pt) and/or gold Au, is patterned by lift-off on each of the gate ohmic contacts 126. The gate overlay metal is used to reduce the metal resistance along the gate finger, since the gate fingers are connected together by a gate bus at the ends of the fingers, as further described below.

The completed device is depicted in FIG. 8. The completed device 100 includes a silicon carbide substrate 102 having a layer arrangement 146 formed thereon. After the ohmic contacts 124/126 and gate overlay metal 128 are formed (for example, as described with reference to FIG. 7), an interlayer dielectric film 131 is deposited by PE-CVD on the passivation film 120, the ohmic contacts, and the gate overlay metal. This film is typically silicon dioxide, with a thickness of about 1.0 μm. Other dielectric films can be used such as silicon oxynitride or silicon nitride; however, it is desirable to minimize the coupling capacitance between the source metal bus 142 and the gate finger regions 132 through the use of the lower dielectric constant material SiO₂. Source contact openings are subsequently patterned and etched using RIE and the source fingers are interconnected through the metal bus 142 using tungsten deposited by CVD. Each of the source regions 133 can be communicatively coupled to the common source bus 142 through each source mesa 108, respectively.

Chemical vapor deposited tungsten (CVD-W) is the preferred source metal interconnect material for two reasons. First, the CVD-W process completely fills the source contact via, which is at or about 0.6 μm in width and at or about 1.0 μm in depth. Second, W has a thermal expansion coefficient (˜4.5) closely matched to that of SiC (˜6.0), which leads to enhanced reliability under RF power cycling. To facilitate the CVD-W process and to further improve reliability, a barrier metal can be deposited prior to the W deposition. This barrier metal is preferably composed of TiN, TiW, TiWN and/or TiWON, or any combination thereof.

As mentioned above, gate overlay metal 128 is used to reduce the metal resistance along the gate finger, and the gate fingers are connected together by a gate bus 140 at the ends of the fingers. Before forming the gate bus 140, gate contact openings are patterned and etched in the interlayer dielectric film 131 using RIE, and thereafter, the metal gate bus 140 is formed; as a result, the gate regions are interconnected through the metal gate bus 140.

After the formation of the source bus 142 and the gate bus 140, source and/or gate bond pads 136 are deposited by liftoff on the source bus 142 and the gate bus 140, respectively. The source and gate bond pads 136 are preferably metal such as Ti, Pt and/or Au, but can be any metal stack suitable for gold wire bonding. A final passivation layer 138 preferably consisting of or including silicon oxynitride having a thickness of at or about 1.0 μm is then deposited, and bond pad openings 150 are patterned and etched using conventional RIE. Thereafter, backside metal 144 suitable for die attach can be deposited. The backside metal 144 can consist of or include a deposited silicon layer for Au/Si eutectic die attach, Ti/Pt/Au, Ti/Ni/Ag or any conventional die attach metal.

As mentioned above, an ideal channel would be of constant width throughout the length of the channel. The source regions 133 include one or more channels 148 having a constant width or a substantially constant width W from the top of the channel mesa 114 to the bottom of the channel mesa 114. In other words, channel mesas 114 are formed between trenches patterned in the substrate 102. The channel mesas 114 are formed to have slanted sidewalls defining a trapezoidal cross section thereof. A source mesa 108 is disposed atop each of the channel mesas 114. The source mesa 108 has sidewalls recessed laterally relative to the sidewalls of the channel mesa 114. A channel 148 is formed in the channel mesa 114 by ion implantation, forming doped regions 132 that extend into the channel mesa 114 through the slanted sidewalls so as to define a substantially rectangular channel 148 between the sidewalls of the channel mesa 114.

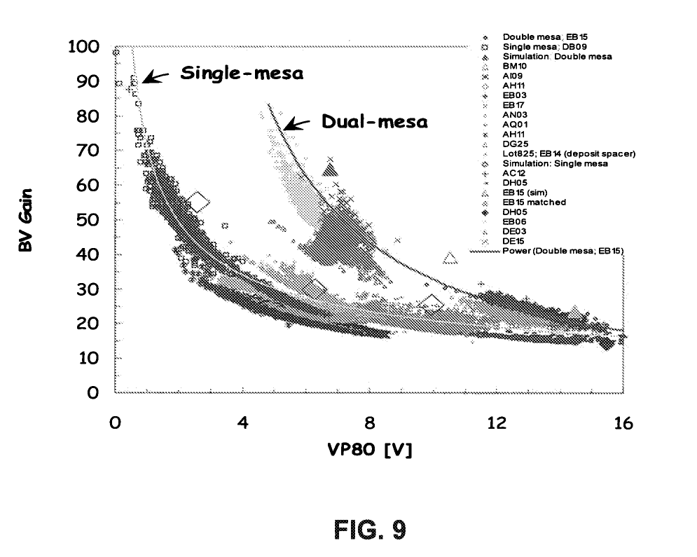

FIG. 9 is a graph comparing the blocking voltage gain performance of the embodiments of the present invention to the prior art. The large-signal power performance of SIT devices is implied by the transistor pinch voltage (V_{P}). Low V_{P} devices exhibit high blocking voltage gain and thus, the possibility of high power gain when transistor transconductance, gₘ, is optimized.

Nevertheless, low V_{P} devices suffer suppressed maximum available current swing in large-signal operations when the gate is moderately turned on as a result of the RF input power. Consequently, low V_{P} devices exhibit limited transistor power delivering capability as indicated by low power at one decibel gain compression (P_{1dB}) due to the suppression of the transistor current swing.

In general, transistor frequency performance is optimized by engineering the cutoff frequency, fₜ. Transistor fₜ is a function of gₘ as well as gate parasitic capacitance (both gate/source and gate/drain junctions). In order to raise SIT switching speed and broaden the spectrum of applications, transistor gₘ is optimized while gate capacitance is minimized.

In prior art single-mesa SIT architectures, transistor V_{P} is adjusted solely by the gate implant for a given epitaxial structure. Therefore, V_{P} targeting in the manufacturing process and transistor small-signal performance are coupled, thereby making it difficult to simultaneously optimize DC, large- and small-signal RF performance.

In other approaches, where the gate is formed by a Schottky metallization instead of acceptor implantation, V_{P} targeting in the manufacturing process is set by the channel mesa width alone for a given gate metal and epitaxial structure. This poses a severe constraint on the final channel mesa width, which translates into limitations in manufacturability. The selection of gate Schottky metal to increase the Schottky junction width is of limited value in terms of relaxing process requirements on the final channel mesa width. The gate junction implant provides significantly greater degree of flexibility, and therefore manufacturability, in the channel mesa formation process.

The dual-mesa SIT architecture, embodiments of which are disclosed herein, has significant performance advantages. For example, in contrast with the single-mesa architecture, the transistor channel length of the dual-mesa SIT can be easily set by channel mesa height. The dual-mesa SIT structure also enables sub-micron transistor channel length with optimized transconductance and minimized gate parasitic capacitance without requiring sub-micron lithography. Moreover, V_{P} is set by both the channel mesa structure and the gate implant, reducing the coupling of V_{P} targeting and transistor channel length. This allows more independent control of DC, large-signal and small-signal RF performance, thereby leading to higher performance and greater manufacturability.

Moreover, for a given transistor pinch voltage, the dual-mesa architecture exhibits much higher transistor blocking voltage gain (as shown in FIG. 9). Together with the high gₘ and low parasitic capacitance, this enables higher frequency RF power performance. Blocking voltage gain information is curve-fit in FIG. 9 to test data indicated by various symbols associated with information such as lot numbers of wafers under test, as set forth in the associated legend.

In addition, due to the high blocking voltage gain intrinsic to the dual-mesa architecture: (a) limitation of power gain as a result of gₘ (channel length) is lessened, and (b) V_{P} can be higher for a given power gain requirement and therefore, channel mesa width can be increased, which translates into improved manufacturability.

Having described and illustrated the principles of the invention in various embodiments thereof, it should be apparent that the invention can be modified in arrangement and detail without departing from such principles. I claim all modifications and variations coming within the spirit and scope of the following claims.

1. A static induction transistor structure, comprising:
a silicon carbide substrate (102) having a layer arrangement (146) formed thereon;
a plurality of laterally spaced ion implanted gate regions (132) defined in the layer arrangement (146); and
a plurality of source regions (133) defined in the layer arrangement (146), each of the plurality of source regions (133) being positioned adjacent to respective ones of the gate regions (132),
wherein:
each of the source regions (133) includes a first mesa (114) having a second mesa (108) disposed thereon;
the second mesa (108) includes upright sidewalls relative to a principal plane of the substrate (102), the principal plane of the substrate (102) defining a horizontal dimension thereof; and
the first mesa (114) includes sidewalls slanted relative to a normal to the principal plane of the substrate (102).

2. The static induction transistor structure of claim 1, wherein at least one of the plurality of source regions (133) further includes a channel (148) having a substantially constant width (W).

3. The static induction transistor structure of claim 1, wherein the first mesa (114) is a channel mesa having at least one slanted sidewall angled at between 2 and 15 degrees from a vertical reference line (115) relative to the principal plane of the substrate (102), the vertical reference line intersecting a vertex located at an upper corner of the first mesa (114).

4. The static induction transistor structure of claim 1, wherein the second mesa (108) for each source region (133) is a source mesa (108) coupled to a source contact (124).

5. The static induction transistor structure of claim 1, wherein the second mesa (108) includes sidewalls that are recessed laterally relative to sidewalls of the first mesa (114).

6. The static induction transistor structure of claim 4, wherein each of the plurality of source regions (133) is communicatively coupled to a source bus (142) through each source mesa (108).

7. The static induction transistor structure of claim 1, further comprising a source ohmic contact (124) coupled to the second mesa (108).

8. The static induction transistor structure of claim 7, further comprising a source bus (142) coupled to the second mesa (108) via the source ohmic contact (124).

9. The static induction transistor structure of claim 8, further comprising an interlayer dielectric film (131) disposed on the passivation film (120) and between the source bus (142) and the plurality of gate regions (132).

10. The static induction transistor structure of claim 8, further comprising a source bond pad (136) formed on the source bus (142).

11. The static induction transistor structure of claim 10, further comprising a passivation layer (138) on the source bond pad (136), wherein the passivation layer includes one or more bond pad openings (150) formed therein.

12. The static induction transistor structure of claim 1, further comprising ohmic contacts (130) coupled to a bottom surface of the substrate, and a backside metal (144) coupled to the ohmic contacts (130).

13. A dual-mesa static induction transistor device, comprising:
a silicon carbide substrate (102);
first and second trenches defined in the substrate (102);
a channel mesa (114) disposed between the first and second trenches, the channel mesa (114) having slanted sidewalls defining a trapezoidal cross section thereof;
a source mesa (108) atop the channel mesa, the source mesa (108) having sidewalls recessed laterally relative to the sidewalls of the channel mesa (114); and
an ion implanted doped region (132) extending into the channel mesa (114) through the slanted sidewalls so as to define a substantially rectangular channel (148) between the sidewalls of the channel mesa (114).

14. A method of fabricating a static induction transistor device (100) on a silicon carbide substrate (102), the method comprising:
forming a silicon carbide contact layer (104) having a first dopant type on the substrate (102);
forming a first implant mask layer (106) on the silicon carbide contact layer (104);
forming a plurality of source mesas (108) in the silicon carbide contact layer (104) using the first implant mask layer (106);
forming a second implant mask layer (110) on the plurality of source mesas (108) and the substrate (102); and
forming a plurality of channel mesas (114) positioned below respective ones of the plurality of source mesas (108), the channel mesas (114) being formed with sidewalls slanted at an angle of between 2 and 15 degrees relative to a normal of a principal plane of the substrate (102).

15. The method of claim 14, further comprising:
implanting ions (103) at a normal relative to the principal plane of the substrate (102) to form a plurality of gate junctions (122) having a dopant type opposite the first dopant type in upper portions of the substrate (102) and lateral portions of the slanted channel mesas (114).

16. The method of claim 15, wherein implanting ions (103) includes forming a plurality of p-type gate junctions (122) and one or more P+guard rings (134).

17. The method of claim 15, wherein implanting ions (103) in upper portions of the substrate (102) and lateral portions of the slanted channel mesas (114) includes forming a channel (148) having a substantially constant width (W).

18. The method of claim 14, further comprising forming a passivation film (120) on the channel mesa (114) and the source mesa (108).

19. A method of fabricating a static induction transistor device (100) on a silicon carbide substrate (102), the method comprising:
forming a silicon carbide contact layer (104) having a first dopant type on the substrate (102);
forming a first implant mask layer (106) on the silicon carbide contact layer (104);
forming a plurality of source mesas (108) in the silicon carbide contact layer (104) using the first implant mask layer (106);
forming a second implant mask layer (110) on the plurality of source mesas (108) and the substrate (102);
forming a plurality of channel mesas (114) positioned below respective ones of the plurality of source mesas (108); and
implanting ions (103) at an acute angle relative to sidewalls of the channel mesas (114) to form a plurality of gate junctions (122) having a dopant type opposite the first dopant type.

20. The method of claim 19, wherein implanting the ions includes implanting at a normal relative to a principal plane of the substrate (102).
